(19) United States
(12) Patent Application Publication
(10) Pub. No.: US 2017/0141316 A1
(43) Pub. Date: May 18, 2017

(54) METHOD FOR MANUFACTURING ORGANIC SEMICONDUCTOR ELEMENT, METHOD FOR MANUFACTURING ORGANIC SEMICONDUCTOR SOLUTION, AND APPLICATION APPARATUS

(71) Applicants: JOLED INC., Tokyo (JP); JAPAN DISPLAY INC., Tokyo (JP)

(72) Inventors: Yasuhiro YAMAUCHI, Tokyo (JP); Shinichiro ISHINO, Tokyo (JP); Koyo SAKAMOTO, Tokyo (JP); Tomohiko ODA, Tokyo (JP)

(73) Assignees: JOLED INC., Tokyo (JP); JAPAN DISPLAY INC., Tokyo (JP)

(21) Appl. No.: 15/347,859

(22) Filed: Nov. 10, 2016

(30) Foreign Application Priority Data
Nov. 12, 2015 (JP) 2015-222502
Sep. 5, 2016 (JP) 2016-173203

(51) Int. Cl. H01L 51/00; B05C 5/02; H01L 51/56

(52) U.S. Cl. CPC H01L 51/0029; H01L 51/56; B05C 5/0208

(57) ABSTRACT

A method for manufacturing an organic semiconductor element including applying an organic semiconductor solution to a base is provided. The method includes, before the applying, bringing a pressure of an inert gas close to an ambient pressure while varying the pressure of the inert gas between a negative pressure and a positive pressure with respect to the ambient pressure. The inert gas is contained in a sealed container together with the organic semiconductor solution. The ambient pressure is a pressure of surroundings of the organic semiconductor solution in the applying.

### CROSS REFERENCE TO RELATED APPLICATIONS

The present application is based on and claims priority of Japanese Patent Applications No. 2015-222502 filed on Nov. 12, 2015 and No. 2016-173203 filed on Sep. 5, 2016. The entire disclosures of the above-identified applications, including the specifications, drawings and claims are incorporated herein by reference in their entirety.

### FIELD

The present disclosure relates to a method for manufacturing an organic semiconductor element, a method for manufacturing an organic semiconductor solution, and an application apparatus.

### BACKGROUND

As an example of an organic semiconductor element, light-emitting element applying an organic electro-luminescence (EL) phenomenon has been known. Such a light-emitting element emits light by recombination of holes and electrons in a light-emitting layer of the element. The light-emitting layer of the light-emitting element is formed by applying a solution containing a luminous composition (an organic semiconductor solution) to a base using an application apparatus, for example, an inkjet printer or the like.

Patent Literature (PTL) 1discloses, in paragraph [0052], a technique of enclosing an organic semiconductor solution and an inert gas in an airtight container, attaching this container to an application apparatus, and then supplying the organic semiconductor solution to the application apparatus. This suppresses deterioration of the organic semiconductor solution caused by exposure to the air.

### CITATION LIST

### Patent Literature

[PTL 1] Japanese Unexamined Patent Application Publication No. 2013-175486

### SUMMARY

### Technical Problem

However, when the inert gas is put in the container together with the organic semiconductor solution as disclosed by PTL 1, the inert gas partially dissolves in the organic semiconductor solution in some cases. Accordingly, in the case where a coating is formed by the application of the organic semiconductor solution, bubbles of the inert gas may be entrained in the coating to be the light-emitting layer.

In view of the above, the present disclosure provides a method for manufacturing an inorganic semiconductor element, etc. that can suppress the deterioration of the organic semiconductor solution and prevent the bubbles from being entrained in the coating formed by the application of the organic semiconductor solution.

### Solution to Problem

In order to solve the problem described above, an aspect of a method for manufacturing an organic semiconductor element including applying an organic semiconductor solution to a base includes, before the applying, bringing a pressure of an inert gas close to an ambient pressure while varying the pressure of the inert gas between a negative pressure and a positive pressure with respect to the ambient pressure. The inert gas is contained in a sealed container together with the organic semiconductor solution. The ambient pressure is a pressure of surroundings of the organic semiconductor solution in the applying.

Furthermore, in order to solve the above-described problem, an aspect of a method for manufacturing an organic semiconductor solution includes enclosing an organic semiconductor solution and an inert gas in a sealed container, and keeping a pressure of the inert gas in the sealed container different from an ambient pressure of surroundings when using the organic semiconductor solution; and after the enclosing and keeping, bringing the pressure of the inert gas in the sealed container close to the ambient pressure while varying the pressure of the inert gas between a negative pressure and a positive pressure with respect to the ambient pressure.

Additionally, in order to solve the above-described problem, an aspect of an application apparatus is an application apparatus that applies an organic semiconductor solution. The application apparatus includes a reservoir part that stores the organic semiconductor solution; and a delivery part that delivers the organic semiconductor solution stored in the reservoir part. The reservoir part stores the organic semiconductor solution prepared by bringing a pressure of an inert gas, which is contained in a sealed container together with the organic semiconductor solution, close to an ambient pressure while varying the pressure of the inert gas between a negative pressure and a positive pressure with respect to the ambient pressure. The ambient pressure is a pressure of surroundings when applying the organic semiconductor solution.

### Advantageous Effects

It becomes possible to suppress the deterioration of the organic semiconductor solution and prevent the bubbles from being entrained in the coating formed by the application of the organic semiconductor solution.

### BRIEF DESCRIPTION OF DRAWINGS

These and other objects, advantages and features of the disclosure will become apparent from the following description thereof taken in conjunction with the accompanying drawings that illustrate a specific embodiment of the present disclosure.

FIG. 1 is a schematic perspective view illustrating organic semiconductor elements (light-emitting elements).

FIG. 2 is a flowchart of an overview of a method for manufacturing the organic semiconductor elements.

FIG. 3 is a flowchart of an overview of a method for manufacturing an EL device in the organic semiconductor elements.

FIG. 4 illustrates an application process and an application apparatus for applying the organic semiconductor solution to a base.

FIG. 5A illustrates a storage state where the organic semiconductor solution and an inert gas are stored in a sealed container before the application process.

FIG. 5B illustrates how an inert gas pressure inside the sealed container is varied.

FIG. 5C illustrates a state where the inert gas pressure inside the sealed container is equal to an ambient pressure, which is the same as that in the application process.

FIG. 6 is a flowchart of a process of varying the inert gas pressure inside the sealed container before the application process.

FIG. 7 illustrates a relationship between the inert gas pressure indicated in FIG. 6 and time.

FIG. 8 illustrates a variation of the sealed container illustrated in FIG. 5B.

### DESCRIPTION OF EMBODIMENT

In the following, a method for manufacturing an organic semiconductor element, a method for manufacturing an organic semiconductor solution, and an application apparatus according to an embodiment will be described with reference to the accompanying drawings. Any embodiment described below will illustrate one specific preferable example of the present disclosure. Thus, the numerical values, shapes, materials, structural components, the arrangement and connection of the structural components, steps and the order of the steps mentioned in the following embodiment are merely an example and not intended to limit the present disclosure. Accordingly, among the structural components in the following embodiment, the one that is not recited in any independent claim exhibiting the most generic concept of the present disclosure will be described as an arbitrary structural component.

Incidentally, each of the figures is a schematic view and not necessarily illustrated in a strict manner. Furthermore, in each of the figures, substantially the same structures are assigned the same reference signs, and the redundant description of such structures will be omitted or simplified.

[1. Schematic Configuration of Organic Semiconductor Elements]

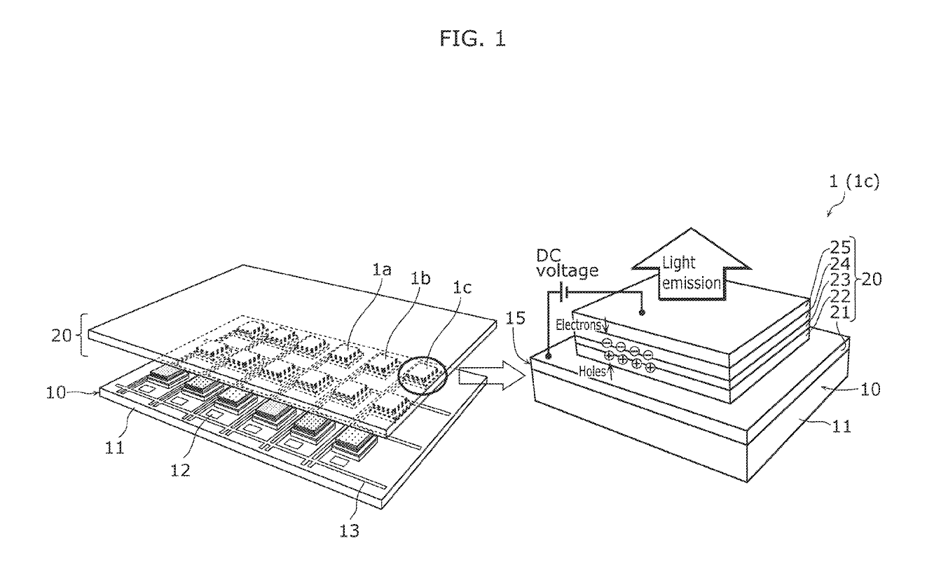

First, as an example of organic semiconductor elements, light-emitting elements applying an organic EL phenomenon will be described. As illustrated in FIG. 1, light-emitting elements 1 include three kinds of light-emitting elements, namely, a red light-emitting element 1a, a green light-emitting element 1b, and a blue light-emitting element 1c, that constitute one pixel. A plurality of the light-emitting elements 1 are arranged in a matrix. A color filter substrate is bonded onto light-emitting surfaces of these light-emitting elements 1, whereby an organic EL display is formed (not shown).

The light-emitting elements 1 include a thin-film-transistor (TFT) substrate 10 and an EL device 20 that are stacked together.

The TFT substrate 10 includes a glass substrate 11, TFTs 12, and signal lines 13. The TFTs 12 and the signal lines 13 are formed on the glass substrate 11. The signal lines 13 serve as power supply lines for driving the TFTs 12. The TFTs 12 serve as semiconductor elements for controlling a current to be supplied to the EL device 20.

The EL device 20 includes an anode 21, a hole injection layer 22, a light-emitting layer 23, an electron injection layer 24, and a cathode 25 that are stacked together. The hole injection layer 22, the light-emitting layer 23, and the electron injection layer 24 of the light-emitting element 1 are partitioned off from the hole injection layer 22, the light-emitting layer 23, and the electron injection layer 24 of the adjacent light-emitting element 1 by a partition wall (bank), which is not shown in this figure. On a lower side of the hole injection layer 22, the anode 21 that reflects light emitted by the light-emitting layer 23 is disposed. On an upper side of the electron injection layer 24, the cathode 25 that transmits the light emitted by the light-emitting layer 23 is disposed.

By applying a DC voltage to the anode 21 and the cathode 25, holes injected from the hole injection layer 22 and electrons injected from the electron injection layer 24 recombine in the light-emitting layer 23. Energy generated by this recombination excites a luminous substance in the light-emitting layer 23, resulting in light emission.

The anode 21 includes two layers of an aluminum alloy and indium zinc oxide (IZO), for example. The hole injection layer 22 is formed of an inorganic material such as tungsten oxide, for example. The light-emitting layer 23 includes a host of a polymeric material and a dopant serving as an emission center when the electrons and the holes are combined. The electron injection layer 24 is formed of an inorganic material prepared by adding barium to a monomeric material, for example. The cathode 25 is formed of an aluminum film, for example.

It is noted that a hole transport layer may be disposed between the hole injection layer 22 and the light-emitting layer 23. An electron transport layer may be disposed between the light-emitting layer 23 and the electron injection layer 24. In order to prevent the electrons from reaching the hole transport layer, an electron blocking layer may be disposed between the hole transport layer and the light-emitting layer 23.

[2. Method for Manufacturing Organic Semiconductor Elements]

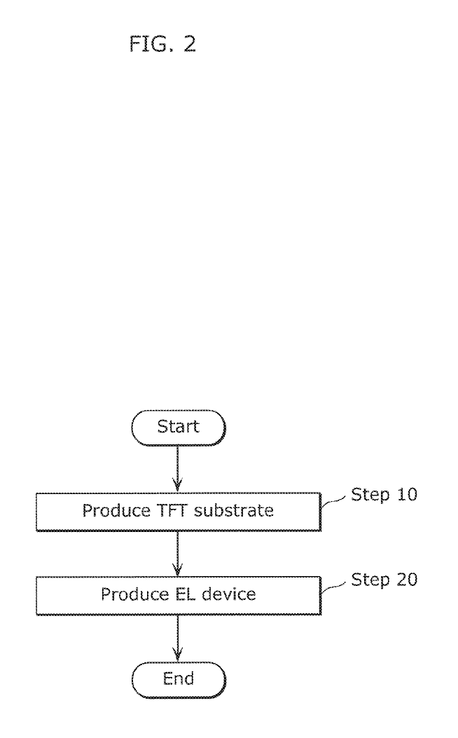

As illustrated in FIG. 2, a method for manufacturing the organic semiconductor element 1 includes a TFT substrate production process of producing the TFT substrate 10 by forming the TFTs 12 on the glass substrate 11 (Step 10), and an EL device production process of producing the EL device 20 on the TFT substrate 10 (Step 20).

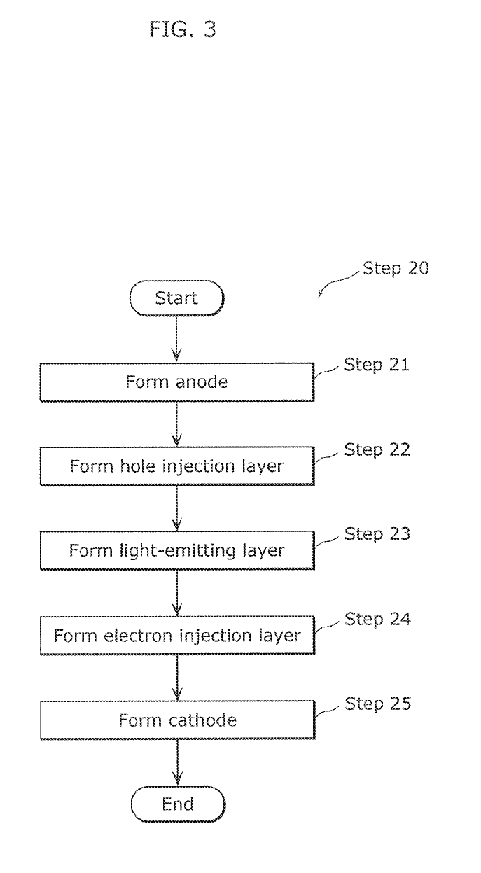

As illustrated in FIG. 3, the EL device production process includes a process of forming the anode 21 (Step 21), a process of forming the hole injection layer 22 (Step 22), a process of forming the light-emitting layer 23 (Step 23: application process), a process of forming the electron injection layer 24 (Step 24), and a process of forming the cathode 25 (Step 25). The following description is directed to an example of the EL device production process.

First, in Step 21, the aluminum alloy film and the IZO film, which are to be the anode 21, are formed sequentially on the TFT substrate 10. The aluminum alloy film and the IZO film are individually formed by sputtering.

Next, in Step 22, a tungsten oxide film, which is to be the hole injection layer 22, is formed on the anode 21. The tungsten oxide film is formed by sputtering.

Subsequently, in Step 23, the light-emitting layer 23 (the red light-emitting layer 23a, the green light-emitting layer 23b, and the blue light-emitting layer 23c) is formed on the base 15 on which the anode 21 and the hole injection layer 22 have been formed. This Step 23 corresponds to the application process in the present embodiment.

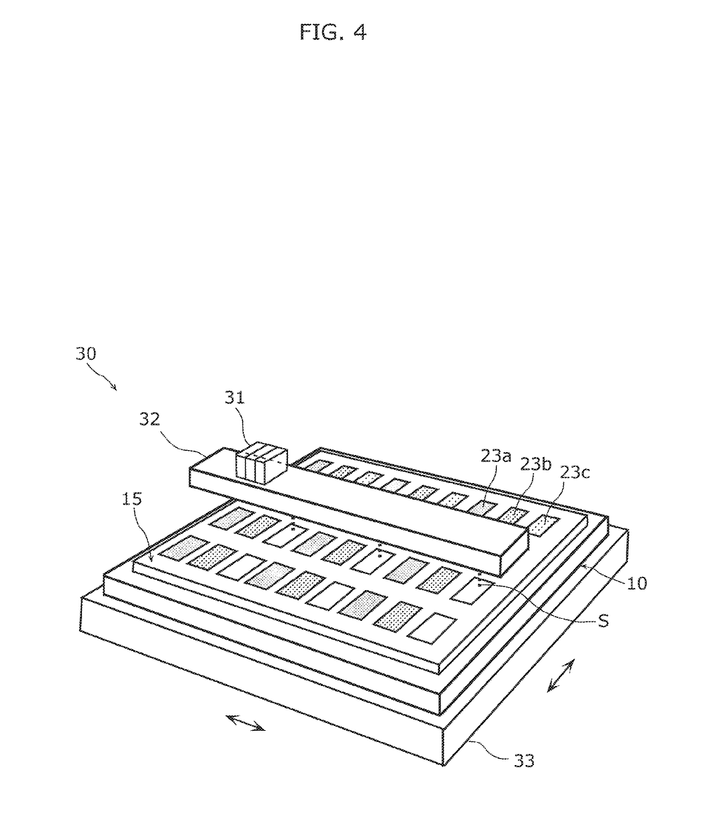

In this process, as illustrated in FIG. 4, an organic semiconductor solution (ink) S is applied using an application apparatus 30 such as an inkjet printer.

The application apparatus 30 includes a reservoir part 31 that stores the organic semiconductor solution 5, and a delivery part 32 that delivers the organic semiconductor solution S stored in the reservoir part 31. The reservoir part 31 is, for example, a box-shaped ink cartridge or a tubular syringe, and connected to the delivery part 32 so as to supply the stored organic semiconductor solution S to the delivery part 32. The delivery part 32 includes a piezoelectric element, and the deformation of the piezoelectric element causes the organic semiconductor solution S in the delivery part 32 to be pushed out and delivered.

On a lower side of the TFT substrate 10, a horizontally movable table 33 that is movable along two orthogonal axes is disposed. By turning on and off the piezoelectric element and controlling the position of the horizontally movable table 33, a predetermined pattern of the organic semiconductor solution is formed on the base 15.

The organic semiconductor solution S contains an organic semiconductor material, which is a luminous composition. The organic semiconductor material can be, for example, a material prepared by adding a dopant to a host of a polymeric material. The organic semiconductor solution S contains an aromatic solvent such as that based on benzene, toluene or xylene. The organic semiconductor material is dispersed in this solvent. The coating of the organic semiconductor solution S applied onto the base 15 is heat-treated or air-dried, whereby the solvent is removed. In this manner, the light-emitting layer 23 is formed on the base 15.

Since bubbles entrained in the coating of the organic semiconductor solution S may cause failures in shape and characteristics of the light-emitting layer 23, it is appropriate that the bubbles entrained in the coating should be reduced as much as possible.

Next, in Step 24, a monomeric material film, which is to be the electron injection layer 24, is formed on the light-emitting layer 23. The monomeric material film is formed by vapor deposition.

Subsequently, in Step 25, an aluminum film, which is to be the cathode 25, is formed on the electron injection layer 24. The aluminum film is formed by vapor deposition.

Through these Steps illustrated in FIG. 2 and FIG. 3, the organic semiconductor elements 1 are produced.

The above description has been directed to an example of forming the light-emitting layer 23 using the application apparatus 30. However, when the hole injection layer 22, the hole transport layer, the electron blocking layer, the electron transport layer, or the electron injection layer 24 is formed of a specific organic semiconductor material, each layer may also be formed by applying a solution containing that organic semiconductor material with the application apparatus 30.

[3. How to Deal with Organic Semiconductor Solution Before Application Process]

Herein, the description will be directed to how to deal with the organic semiconductor solution S before the above-described application process (Step 23), namely, a method for manufacturing the organic semiconductor solution S.

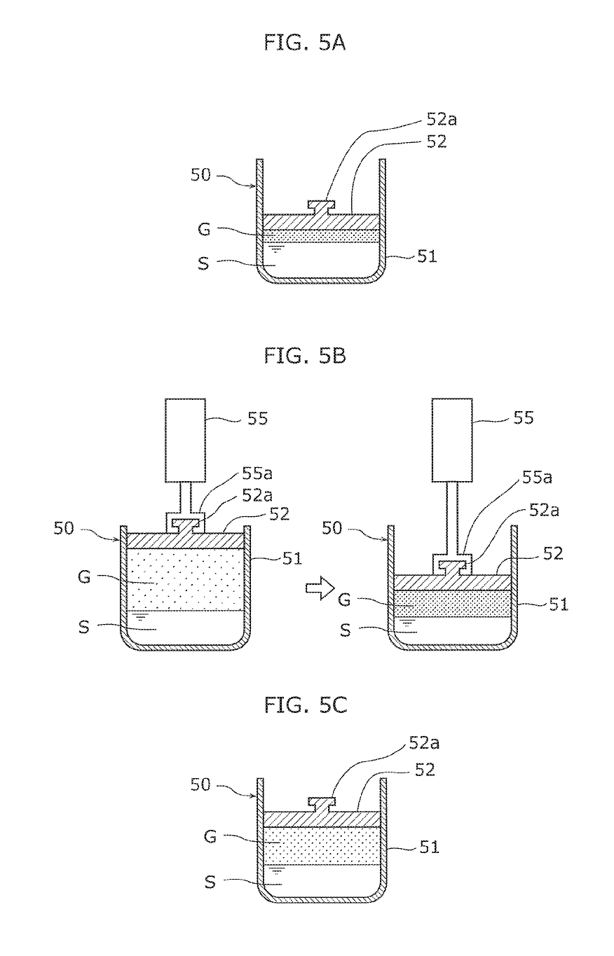

Before the application process, the organic semiconductor solution S is stored in a sealed container 50 together with an inert gas G as illustrated in FIG. 5A.

The sealed container 50 includes a container main body 51 in a shape of a bottomed cylinder, and a disc-shaped lid 52 that is in contact with an inner surface of the container main body 51. An outer periphery of the lid 52 is provided with a sealing material (not shown). This sealing material maintains airtightness in the sealed container 50. The lid 52 is slidable along the inner surface of the container main body 51. An engagement part 52a that protrudes like a flange is provided at the center of the lid 52. By grasping this engagement part 52a and moving the lid 52 vertically, the volume of the sealed container 50 can be varied (see FIG. 5B). The container main body 51 and the lid 52 (except the sealing material) are formed of a material such as stainless steel, for example.

The organic semiconductor solution S is an ink for forming the light-emitting layer 23. The organic semiconductor solution S contains an aromatic solvent such as that based on benzene, toluene or xylene. The organic semiconductor material is dispersed in this solvent. The organic semiconductor material can be, for example, a material prepared by adding a dopant to a host of a polymeric material.

In order to prevent the organic semiconductor solution S from being exposed to the air and oxidized, the inert gas G is filled in the sealed container 50 in such a manner as to cover an upper portion of the organic semiconductor solution S. The inert gas G can be, for example, nitrogen, helium, or argon gas. It should be noted that the inert gas G is not limited to the above as long as it is inert toward the solvent of the organic semiconductor solution S. The pressure of the inert gas G in the sealed container 50 is kept different from the ambient pressure Pe of the surroundings in the application process where the organic semiconductor solution S is used. In the present embodiment, the inert gas G that is compressed is sealed in the sealed container 50.

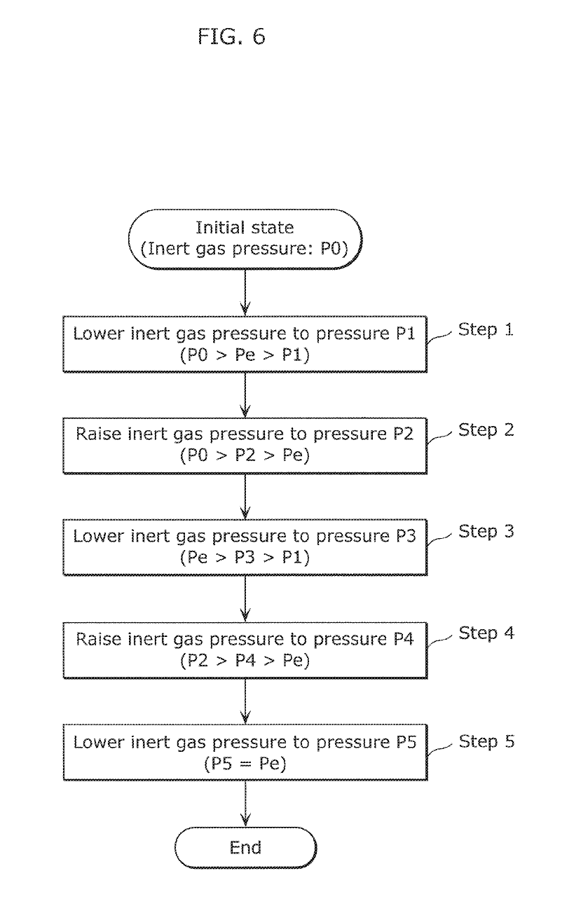

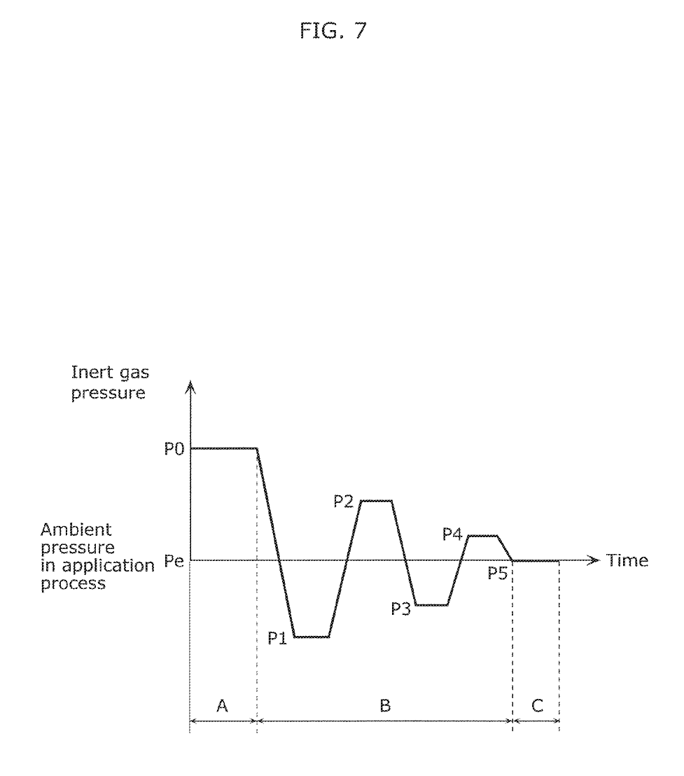

Now, referring to FIG. 6 and FIG. 7, a process of varying the pressure of the inert gas G in the sealed container 50 will be explained.

In period A illustrated in FIG. 7, the organic semiconductor solution S is stored in the sealed container 50. In period B, the pressure of the inert gas G in the sealed container 50 is varied. In period C, the pressure of the inert gas G in the sealed container 50 is equal to the ambient pressure Pe of the surroundings of the organic semiconductor solution S in the application process (equal to the pressure of a gas that is in contact with the organic semiconductor solution S enclosed in the application apparatus 30). Incidentally, it is appropriate that the temperature in period B should be equal to that in period C.

The present embodiment is characterized by bringing the pressure of the inert gas G in the sealed container 50 close to the ambient pressure Pe while varying it to a negative pressure and a positive pressure before the application process. Herein, the positive pressure in the present embodiment means a pressure on a positive side with respect to the ambient pressure Pe, and the negative pressure means a pressure on a negative side with respect to the ambient pressure Pe. For example, when the ambient pressure Pe is atmospheric pressure, the inert gas G in the sealed container 50 is brought close to the atmospheric pressure while it is varied to the negative pressure and the positive pressure with respect to the atmospheric pressure.

As described above, when the organic semiconductor solution S is stored, the compressed inert gas G is sealed in the sealed container 50. Thus, the inert gas G is at the positive pressure. This state is referred to as an initial state, and the pressure of the inert gas G at this time is given by P0 (for example, 2 atm=202650 Pa).

First, in Step 1, the pressure of the inert gas G is lowered to pressure P1 (for example, 0.5 atm=50662.5 Pa). More specifically, as illustrated in FIG. 5B, after a grasping part 55a of a drive means 55 such as a uniaxial robot is engaged with the engagement part 52a of the lid 52, the lid 52 is lifted up by the drive means 55, thereby gradually increasing the volume of the sealed container 50. In this manner, the pressure of the inert gas G is lowered gradually to a negative pressure (P0>Pe>P1). Then, this pressure P1 is kept for a predetermined period.

In subsequent Step 2, the pressure of the inert gas G is raised to pressure P2 (for example, 1.3 atm=131722.5 Pa), More specifically, as illustrated in FIG. 5B, the lid 52 of the sealed container 50 is lowered, thereby gradually reducing the volume of the sealed container 50. In this manner, the pressure of the inert gas G is gradually raised to a positive pressure. Pressure P2 at this time is less than pressure P0 at the initial state and greater than the ambient pressure Pe (P0>P2>Pe). Then, this pressure P2 is kept for a predetermined period.

In subsequent Step 3, the pressure of the inert gas G is lowered to pressure P3 (for example, 0.8 atm=81060 Pa). More specifically, the lid 52 of the sealed container 50 is lifted up, thereby gradually increasing the volume of the sealed container 50. In this manner, the pressure of the inert gas G is gradually lowered to a negative pressure. Pressure P3 at this time is less negative than Pressure P1 described earlier and less than the ambient pressure Pe (Pe>P3>P1). Then, this pressure P3 is kept for a predetermined period.

In subsequent Step 4, the pressure of the inert gas G is raised to pressure P4 (for example, 1.1 atm=111457.5 Pa). More specifically, the lid 52 of the sealed container 50 is lowered, thereby gradually reducing the volume of the sealed container 50. In this manner, the pressure of the inert gas G is gradually lowered to a positive pressure. Pressure P4 at this time is less than pressure P2 described earlier and greater than the ambient pressure Pe (P2>P4>Pe). Then, this pressure P4 is kept for a predetermined period.

In final Step 5, the pressure of the inert gas G is lowered so that pressure P5 becomes equal to the ambient pressure Pe. More specifically, the lid 52 of the sealed container 50 is lifted up, thereby gradually increasing the volume of the sealed container 50 so as to bring pressure P5 equal to the ambient pressure Pe (P5=Pe). When the ambient pressure Pe is at atmospheric pressure, pressure P5 is 101325 Pa.

As described above, the pressure of the inert gas G is varied so that the difference between the positive pressure after pressure variation and the ambient pressure Pe and the difference between the negative pressure after the pressure variation and the ambient pressure Pe decrease in stages. These processes allow degassing (removal of the inert gas G) from the organic semiconductor solution S.

The organic semiconductor solution S after the degassing is supplied to the application apparatus 30 while being isolated from the external air. It should be noted that, if the surroundings in the application process are filled with the same inert gas, the organic semiconductor solution S may also be supplied to the application apparatus 30 while the lid 52 of the sealed container 50 is kept open.

In the present embodiment, before the application process, the pressure of the inert gas G in the sealed container 50 is brought close to the ambient pressure Pe while varying the pressure of the inert gas G back and forth between the negative pressure and the positive pressure. This allows appropriate degassing of the inert gas G dissolving in the organic semiconductor solution (ink) S. As a result, it becomes possible to suppress the deterioration of the organic semiconductor solution S and prevent the bubbles from being entrained in the coating formed by the application of the organic semiconductor solution S.

Incidentally, when the organic semiconductor solution S in which the bubbles are entrained is supplied to the application apparatus 30, clogging may occur in the application apparatus 30, or the application amounts or application positions of the coating to be applied to the base 15 may vary in some cases. However, in the present embodiment, since the bubbles can be removed appropriately from the organic semiconductor solution S, it becomes possible to suppress the clogging in the application apparatus 30 and reduce the variations in the application amount and the application position. In other words, the present embodiment makes it possible to prevent the bubbles from being entrained not only in the coating but also in the application apparatus 30.

Furthermore, by varying the pressure of the inert gas G back and forth between the negative pressure and the positive pressure, the degassing can be performed in a short time. Consequently, it becomes possible to achieve a shorter manufacturing time of the organic semiconductor elements 1.

Moreover, by bringing the pressure of the inert gas G to not only the negative pressure but also the positive pressure, abrupt evaporation of the solvent of the organic semiconductor solution S can be suppressed. As a result, variations in the concentration of the organic semiconductor solution S decrease, making it possible to improve the quality of the coating of the organic semiconductor solution S.

Incidentally, the present embodiment has been directed to the example in which the pressure of the inert gas G in the sealed container 50 is brought to the positive pressure three times and the negative pressure twice. However, there is no particular limitation to this. The pressure of the inert gas G may be brought to the positive pressure once and the negative pressure once. For example, in FIG. 7, pressure P2 is not set to the positive pressure but may be equal to the ambient pressure Pe at this stage.

Furthermore, the present embodiment has been directed to the example in which the positive pressure and the negative pressure are switched by varying the volume of the sealed container 50. However, there is no particular limitation to this. For example, the pressure of the inert gas G may be brought closer to the ambient pressure Pe while ultrasonically causing pressure variations in the sealed container 50.

Additionally, the present embodiment has been directed to the example in which the pressure of the inert gas G is brought to the positive pressure and then equal to the ambient pressure Pe. However, there is no particular limitation to this. It is also possible to bring the pressure of the inert gas G to the negative pressure and then equal to the ambient pressure Pe. For example, in FIG. 7, it may be possible to set pressure P4 not to the positive pressure but equal to the ambient pressure Pe at this stage. Alternatively, in FIG. 7, it is also possible to once set pressure P5 to the negative pressure and then equal to the ambient pressure Pe.

Moreover, the inert gas G in the case of storing the organic semiconductor solution S in the sealed container 50 may be at a negative pressure. When the inert gas G is at a negative pressure, it is possible to reduce the amount of the inert gas G dissolving in the organic semiconductor solution S. When the inert gas G in the initial state in FIG. 6 is at a negative pressure, it is appropriate to bring the pressure of the inert gas G to a positive pressure in the first step and to a negative pressure in the next step, and repeat this varying process to bring the inert gas pressure closer to the ambient pressure Pe.

In the application process, in order to suppress the entry of the external air, the ambient pressure Pe is set to be higher than atmospheric pressure in some cases. In that case, it is appropriate that pressure P5 of the inert gas G in the final Step 5 in FIG. 6 should be equal to the ambient pressure Pe, which is set to be higher than the atmospheric pressure.

Also, in the application process, in order to dry the coating of the organic semiconductor solution S quickly, the ambient pressure Pe is set to be lower than atmospheric pressure in some cases. In that case, it is appropriate that pressure P5 of the inert gas G in the final Step 5 in FIG. 6 should be equal to the ambient pressure Pe, which is set to be lower than the atmospheric pressure.

(Variation)

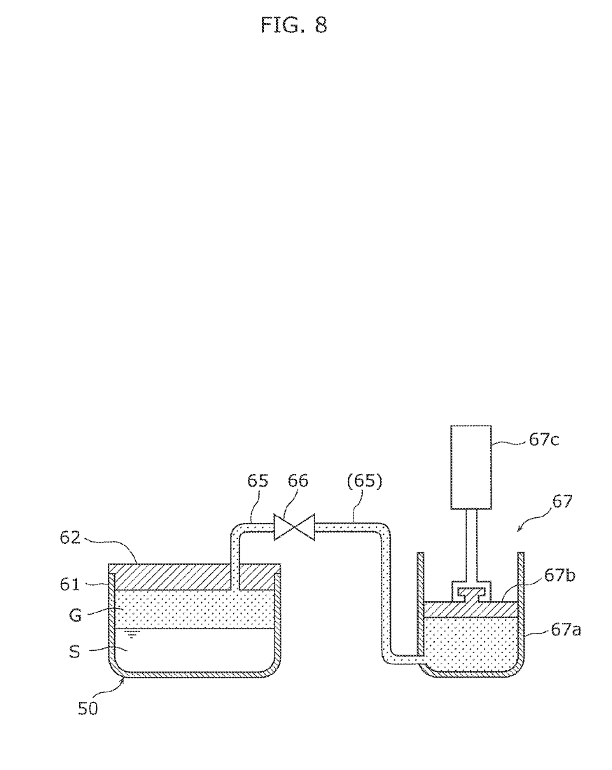

FIG. 8 illustrates a variation in the case of varying the pressure of the inert gas G in the sealed container 50. Incidentally, the structural components that are in common with the sealed container 50 illustrated in FIG. 5B will be assigned the same reference signs, and the description thereof will be omitted here.

The sealed container 50 in the present variation includes a container main body 61 in a shape of a bottomed cylinder, and a disc-shaped lid 62 with a flange. The lid 62 is fixed to an upper portion of the container main body 61 so as to maintain airtightness in the sealed container 50.

One end of a pipe 65 that is in communication with an inner portion of the sealed container 50 is attached to the sealed container 50. A middle portion of the pipe 65 is provided with an open/close valve 66. A supply/discharge means 67 that supplies and discharges the inert gas G is attached to the other end of the pipe 65. The supply/discharge means 67 is a reciprocating piston mechanism, and includes a fixed cylinder 67a, a movable piston 67b, and an actuator 67c. Inside the fixed cylinder 67a is filled with an inert gas G of the same kind and at the same pressure as the inert gas G in the sealed container 50. By opening the open/close valve 66 and operating the supply/discharge means 67, it is possible to discharge the inert gas G from the sealed container 50 or supply the inert gas G to the sealed container 50.

As illustrated in this variation, the inert gas G is supplied to and discharged from the sealed container 50, thereby varying the pressure of the inert gas G in the sealed container 50 to a positive pressure or a negative pressure. An advantageous effect similar to the above-described embodiment can be achieved also in the case of varying the pressure in this variation.

[4. Summary]

As described above, the method for manufacturing the organic semiconductor elements 1 includes applying an organic semiconductor solution S to a base 15, and includes, before the applying, bringing a pressure of an inert gas G close to an ambient pressure Pe while varying the pressure of the inert gas G between a negative pressure and a positive pressure with respect to the ambient pressure Pe. The inert gas G is contained in a sealed container 50 together with the organic semiconductor solution S. The ambient pressure Pe is a pressure of surroundings of the organic semiconductor solution S in the applying.

The above configuration allows appropriate degassing of the inert gas G (removal of the inert gas G) dissolving in the organic semiconductor solution S. As a result, it becomes possible to suppress the deterioration of the organic semiconductor solution S and prevent the bubbles from being entrained in the coating formed by the application of the organic semiconductor solution S. Furthermore, by varying the pressure of the inert gas G in the sealed container 50 back and forth between the negative pressure and the positive pressure, the degassing can be performed in a short time. Consequently, it becomes possible to achieve a shorter manufacturing time of the organic semiconductor elements 1. Moreover, by bringing the pressure of the inert gas G in the sealed container 50 to not only the negative pressure but also the positive pressure, abrupt evaporation of the solvent of the organic semiconductor solution S can be suppressed. As a result, variations in the concentration of the organic semiconductor solution S decrease, making it possible to improve the quality of the coating of the organic semiconductor solution S. This improves the quality of the light-emitting layer 23 of the organic semiconductor elements 1 formed of the coating of the organic semiconductor solution S.

Furthermore, in the method for manufacturing the organic semiconductor elements 1, the pressure of the inert gas G may be varied so that a difference between the positive pressure and the ambient pressure Pe and a difference between the negative pressure and the ambient pressure Pe decrease in stages.

With this configuration, since the process goes on while an amount of degassing of the inert gas G and an evaporation amount of the solvent in the organic semiconductor solution S are decreasing in stages, it is possible to suppress the deterioration of the organic semiconductor solution S. Consequently, the bubbles can be prevented from being entrained in the coating formed by applying the organic semiconductor solution S. Also, variations in the concentration of the organic semiconductor solution S decrease, making it possible to improve the quality of the coating of the organic semiconductor solution S.

Moreover, in the method for manufacturing the organic semiconductor elements 1, the pressure of the inert gas G may be varied by varying a volume of the sealed container 50.

With this configuration, the pressure of the inert gas G can be varied easily, thus simplifying the process of manufacturing the organic semiconductor elements 1.

Also, in the method for manufacturing the organic semiconductor elements 1, the pressure of the inert gas G may be varied by discharging the inert gas G from the sealed container 50 or by supplying the inert gas G to the sealed container 50.

With this configuration, the pressure of the inert gas G can be varied to have a desired value, thus achieving appropriate degassing.

Additionally, the inert gas G before the varying may be at a positive pressure, and when varying the pressure of the inert gas G, the pressure of the inert gas G may be varied from the positive pressure to the negative pressure and then back to the positive pressure.

With this configuration, before the pressure of the inert gas G is varied, the inert gas G is at a positive pressure. Thus, it is possible to suppress the entry of impurity gas from an outside of the sealed container 50. Also, even when the amount of the inert gas G dissolving in the organic semiconductor solution S is large, the degassing can be performed appropriately by varying the pressure of the inert gas G from the positive pressure to the negative pressure. As a result, it becomes possible to suppress the entrainment of bubbles in the coating of the organic semiconductor solution S and the entry of impurities thereinto, thus improving the quality of the coating of the organic semiconductor solution S.

Also, the ambient pressure Pe may be equal to atmospheric pressure.

With this configuration, the pressure variations at the time of using the organic semiconductor solution S in the application process decrease, thus making it possible to improve the quality of the coating of the organic semiconductor solution S.

Also, the ambient pressure Pe may be higher than atmospheric pressure.

With this configuration, even when the ambient pressure Pe of the surroundings of the organic semiconductor solution S in the application process is higher than atmospheric pressure, the pressure variations depending on usage environment decrease, so that the quality of the coating of the organic semiconductor solution S can be improved.

Furthermore, the method for manufacturing the organic semiconductor solution S includes enclosing an organic semiconductor solution S and an inert gas G in a sealed container 50, and keeping a pressure of the inert gas G in the sealed container 50 different from an ambient pressure Pe of surroundings when using the organic semiconductor solution S (Step 0); and after the enclosing and keeping (Step 0), bringing the pressure of the inert gas G in the sealed container 50 close to the ambient pressure Pe while varying the pressure of the inert gas G between a negative pressure and a positive pressure with respect to the ambient pressure Pe (Steps 1 to 5).

The above-described method for manufacturing the organic semiconductor solution S allows appropriate degassing of the inert gas G dissolving in the organic semiconductor solution S. As a result, it becomes possible to suppress the deterioration of the organic semiconductor solution S and prevent the bubbles from being entrained in the coating formed by the application of the organic semiconductor solution S. Furthermore, by varying the pressure of the inert gas G in the sealed container 50 back and forth between the negative pressure and the positive pressure, the degassing can be performed in a short time. Consequently, it becomes possible to achieve a shorter manufacturing time of the organic semiconductor solution S. Moreover, by bringing the pressure of the inert gas G in the sealed container 50 to not only the negative pressure but also the positive pressure, abrupt evaporation of the solvent of the organic semiconductor solution S can be suppressed. As a result, variations in the concentration of the organic semiconductor solution S decrease, making it possible to improve the quality of the coating of the organic semiconductor solution S.

Additionally, the application apparatus 30 that applies the organic semiconductor solution S includes a reservoir part 31 that stores the organic semiconductor solution S; and a delivery part 32 that delivers the organic semiconductor solution S stored in the reservoir part 31. The reservoir part 31 stores the organic semiconductor solution S prepared by bringing a pressure of an inert gas G, which is contained in a sealed container 50 together with the organic semiconductor solution 5, close to an ambient pressure Pe while varying the pressure of the inert gas G between a negative pressure and a positive pressure with respect to the ambient pressure Pe. The ambient pressure Pe is a pressure of surroundings when applying the organic semiconductor solution S. With the use of the organic semiconductor solution S that has been subjected to appropriate degassing of the inert gas G as in the application apparatus 30 described above, it is possible to prevent the bubbles from being entrained in the coating formed by the application apparatus 30. Also, since the entrainment of bubbles can be suppressed, the production efficiency can be enhanced. Moreover, with the use of the organic semiconductor solution S having small concentration variations that is obtained by suppressing abrupt evaporation of the solvent of the organic semiconductor solution 5, it becomes possible to improve the quality of the coating formed by the application apparatus 30.

In the above description, the method for manufacturing an organic semiconductor element, the method for manufacturing an organic semiconductor solution, and the application apparatus have been discussed with reference to an embodiment. However, the present disclosure is by no means limited to the above-described embodiment. For example, a mode obtained by making various modifications conceivable by a person skilled in the art to the above embodiment and a mode configured by the arbitrary combination of the structural components and functions in the embodiment as long as not departing from the purport of the present disclosure fall within the scope of the present disclosure.

For instance, the organic semiconductor solution is not limited to the above-mentioned ink containing a luminous composition, but may be an ink for forming the hole injection layer, the hole transport layer, the electron blocking layer, the electron transport layer, or the electron injection layer. Moreover, the organic semiconductor solution may also be a dispersed solution containing electrically-conductive powder, pigments or the like. In addition, the application apparatus is by no means limited to the inkjet printer but may be a nozzle dispenser or a spray.

Although only some exemplary embodiment of the present disclosure has been described in detail above, those skilled in the art will readily appreciate that many modifications are possible in the exemplary embodiment without materially departing from the novel teachings and advantages of the present disclosure. Accordingly, all such modifications are intended to be included within the scope of the present disclosure.

### INDUSTRIAL APPLICABILITY

The present disclosure is applicable to a method for manufacturing an organic EL display apparatus used in a display device, for example. cm 1. A method for manufacturing an organic semiconductor element including applying an organic semiconductor solution to a base, the method comprising
before the applying, bringing a pressure of an inert gas close to an ambient pressure while varying the pressure of the inert gas between a negative pressure and a positive pressure with respect to the ambient pressure, the inert gas being contained in a sealed container together with the organic semiconductor solution, the ambient pressure being a pressure of surroundings of the organic semiconductor solution in the applying.

2. The method according to claim 1,
wherein the pressure of the inert gas is varied so that a difference between the positive pressure and the ambient pressure and a difference between the negative pressure and the ambient pressure decrease in stages.

3. The method according to claim 1,
wherein the pressure of the inert gas is varied by varying a volume of the sealed container.

4. The method according to claim 1,
wherein the pressure of the inert gas is varied by discharging the inert gas frorn the sealed container or by supplying the inert gas to the sealed container.

5. The method according to claim 1,
wherein the inert gas before the varying is at a positive pressure, and
when varying the pressure of the inert gas, the pressure of the inert gas is varied from the positive pressure to the negative pressure and then back to the positive pressure.

6. The method according to claim 1,
wherein the ambient pressure is equal to atmospheric pressure.

7. The method according to claim 1,
wherein the ambient pressure is higher than atmospheric pressure.

8. A method for manufacturing an organic semiconductor solution, the method comprising:
enclosing an organic semiconductor solution and an inert gas in a sealed container, and keeping a pressure of the inert gas in the sealed container different from an ambient pressure of surroundings when using the organic semiconductor solution; and
after the enclosing and keeping, bringing the pressure of the inert gas in the sealed container close to the ambient pressure while varying the pressure of the inert gas between a negative pressure and a positive pressure with respect to the ambient pressure.

9. An application apparatus that applies an organic semiconductor solution, the application apparatus comprising:
a reservoir part that stores the organic semiconductor solution; and
a delivery part that delivers the organic semiconductor solution stored in the reservoir part,
wherein the reservoir part stores the organic semiconductor solution prepared by bringing a pressure of an inert gas, which is contained in a sealed container together with the organic semiconductor solution, close to an ambient pressure while varying the pressure of the inert gas between a negative pressure and a positive pressure with respect to the ambient pressure, the ambient pressure being a pressure of surroundings when applying the organic semiconductor solution.
